(19) United States
(12) Patent Application Publication
(10) Pub. No.: US 2015/0049510 A1
(43) Pub. Date: Feb. 19, 2015

(54) RADIATION-EMITING SEMICONDUCTOR COMPONENT, LIGHTING DEVICE AND DISPLAY DEVICE

(71) Applicant: OSRAM Opto Semiconductors GmbH, Regensburg (DE)

(72) Inventors: Luca Haiberger, Regensburg (DE); Georg Bogner, Lappersdorf (DE)

(21) Appl. No.: 14/384,092

(22) PCT Filed: Mar. 12, 2013
(86) PCT No.: PCT/EP2013/055001

§ 371 Date: Sep. 9, 2014

(30) Foreign Application Priority Data
Mar. 13, 2012 (DE) 10 2012 102 114.7

(51) Int. Cl. H01L 33/46; F21V 8/00; G02F 1/1335; H01L 33/52

(52) U.S. Cl. CPC H01L 33/46; H01L 33/52; G02B 6/0073; G02B 6/0068; G02F 1/1336
USPC 362/612; 257/98

(57) ABSTRACT

A radiation-emitting semiconductor component including a volume-emitting semiconductor chip including a first main surface and a second main surface opposite the first main surface, a first reflective element arranged at the first main surface and reflects electromagnetic radiation emerging through the first main surface during operation of the semiconductor chip back to the first main surface, a second reflective element arranged at the second main surface and reflects electromagnetic radiation emerging through the second main surface during operation of the semiconductor chip back to the second main surface, and at least one radiation exit surface through which electromagnetic radiation generated during the operation of the semiconductor component emerges from the semiconductor component, wherein the at least one radiation exit surface runs transversely with respect to the first main surface and the second main surface of the semiconductor chip.

### TECHNICAL FIELD

This disclosure relates to radiation-emitting semiconductor components, lighting devices and display devices comprising such radiation-emitting semiconductor components, wherein semiconductor components whose emitted electromagnetic radiation can be utilized particularly efficiently.

### SUMMARY

We provide a radiation-emitting semiconductor component including a volume-emitting semiconductor chip comprising a first main surface and a second main surface opposite the first main surface, a first reflective element arranged at the first main surface and reflects electromagnetic radiation emerging through the first main surface during operation of the semiconductor chip back to the first main surface, a second reflective element arranged at the second main surface and reflects electromagnetic radiation emerging through the second main surface during operation of the semiconductor chip back to the second main surface, and at least one radiation exit surface through which electromagnetic radiation generated during the operation of the semiconductor component emerges from the semiconductor component, wherein the at least one radiation exit surface runs transversely with respect to the first main surface and the second main surface of the semiconductor chip.

We also provide a lighting device including an optical waveguide, and a radiation-emitting semiconductor component according to claim 17, wherein the optical waveguide comprises a cutout, the radiation-emitting semiconductor component is arranged in the cutout, and the optical waveguide surrounds the semiconductor component at at least one of the radiation exit surfaces.

We further provide a display device including a lighting device according to claim 29, and an imaging element, wherein the lighting device backlights the imaging element, and the radiation exit surface of the optical waveguide faces the imaging element.

### BRIEF DESCRIPTION OF THE DRAWINGS

FIGS. 1A to 1C show schematic sectional illustrations of a first production method of producing one example of a semiconductor component.

FIGS. 2A to 2C show schematic sectional illustrations of a further method of producing one example of a semiconductor component described here.

FIGS. 3, 4, 5, 6, 7A, 7B and 7C show schematic sectional illustrations of further examples of semiconductor components and lighting devices described.

FIG. 8 shows schematic sectional illustrations of a display device described here.

### DETAILED DESCRIPTION

The radiation-emitting semiconductor component may comprise a volume-emitting semiconductor chip. That is to say that the semiconductor chip is a volume emitter. In particular, in a volume emitter, without additional measures such as a reflective coating, for example, at the outer surface, a radiation proportion generated during the operation of the semiconductor chip and amounting, for example, to more than 20% or more than 40% of a radiation coupled out in total from the semiconductor chip leaves the semiconductor chip via side surfaces. That is to say that, in a volume emitter, a large part of the electromagnetic radiation leaving the semiconductor chip is not coupled out via a main surface. Rather, an appreciable proportion of electromagnetic radiation also emerges at side surfaces of the semiconductor chip that run transversely with respect to the main surface, for example, a top surface and a bottom surface, of the semiconductor chip.

The volume-emitting semiconductor chip is formed, for example, with an epitaxially grown semiconductor body applied to a radiation-transmissive carrier. The radiation-transmissive carrier can be, for example, a growth substrate for the semiconductor body. In particular, the carrier can be a sapphire growth substrate. For example, more than 20% or more than 40% of the radiation coupled out in total from the semiconductor chip then leaves the semiconductor chip through an outer surface of the radiation-transmissive carrier.

The semiconductor chip comprises a first main surface and a second main surface situated opposite the first main surface. By way of example, the first main surface is a bottom surface of the semiconductor chip and the second main surface is a top surface of the semiconductor chip. The two main surfaces of the semiconductor chip connect to one another via at least one side surface which runs transversely with respect to the main surfaces.

The radiation-emitting semiconductor component may comprise a first reflective element arranged at the first main surface and reflects electromagnetic radiation emerging through the first main surface during operation of the semiconductor chip back to the first main surface. That is to say that the first reflective element is situated at the bottom surface of the semiconductor chip, for example, and ensures that electromagnetic radiation emerging at the bottom surface is reflected back in the direction of the bottom surface. The radiation then need not necessarily impinge on the first main surface of the semiconductor chip again, but rather can be reflected past the semiconductor chip, for example. However, the beam direction of the reflected radiation has a component facing away from a reflective element in the direction of the first main surface.

In this case, the first reflective element can reflect diffusely or directionally.

The semiconductor component may comprise a second reflective element arranged at the second main surface of the semiconductor chip and reflects electromagnetic radiation emerging through the second main surface during operation of the semiconductor chip back to the second main surface. In other words, the second reflective element reflects electromagnetic radiation emerging at a top surface of the semiconductor chip, for example, back in the direction of the top surface. That is to say that the beam direction of the reflected radiation has a component facing in the direction of the top surface from the second reflective element. The second reflective element, too, can reflect directionally or diffusely.

The radiation-emitting semiconductor component may comprise at least one radiation exit surface through which electromagnetic radiation generated during operation of the semiconductor component emerges from the semiconductor component. The radiation-emitting semiconductor component can comprise, for example, exactly one radiation exit surface or a plurality of radiation exit surfaces.

At least one of the radiation exit surfaces of the semiconductor component may run transversely with respect to the first main surface and the second main surface of the semiconductor chip. In this case, it is also possible for all the radiation exit surfaces of the semiconductor component to run transversely with respect to the first main surface and the second main surface of the semiconductor chip.

It is possible, for example, for the radiation exit surfaces to run perpendicularly to the main surfaces of the semiconductor chip at least in places. While the semiconductor chip used in the radiation-emitting semiconductor component is therefore volume-emitting and couples out electromagnetic radiation through its side surfaces and at least one main surface, the radiation-emitting semiconductor component emits the electromagnetic radiation generated by the semiconductor chip at least predominantly or completely through radiation exit surfaces that run transversely with respect to the main surfaces. Therefore, the radiation-emitting semiconductor component is not volume-emitting, for example, but rather emits only toward the side or in the direction of its sides. A laterally emitting radiation-emitting semiconductor component thus results.

The semiconductor component may comprise a volume-emitting semiconductor chip comprising a first main surface and a second main surface opposite the first main surface, a first reflective element arranged at the first main surface and reflects electromagnetic radiation emerging through the first main surface during the operation of the semiconductor chip back to the first main surface, a second reflective element arranged at the second main surface and reflects electromagnetic radiation emerging through the second main surface during operation of the semiconductor chip back to the second main surface, and at least one radiation exit surface through which electromagnetic radiation generated during the operation of the semiconductor component emerges from the semiconductor component. In this case, the at least one radiation exit surface runs or all of the radiation exit surfaces of the semiconductor component run transversely with respect to the first main surface and the second main surface of the semiconductor chip.

In this case, the radiation-emitting semiconductor component is based on the insight, inter alia, that a very flat, laterally emitting semiconductor component can be produced with the aid of a volume-emitting semiconductor chip in which emergence of radiation through the main surfaces is deflected toward the side by reflective elements. Light from such a semiconductor component can be coupled into planar optical waveguides very efficiently, for example. Furthermore, the emission characteristic of the electromagnetic radiation emitted by the semiconductor component during operation can be influenced by the configuration of the reflective elements, for example, such that, to shape the emission characteristic, it is possible to dispense with secondary optical elements.

The second reflective element may completely cover the second main surface of the volume-emitting semiconductor chip. In this case, the second reflective element can directly adjoin the second main surface or is arranged at a distance from the second main surface. In a plane parallel to or congruent with the second main surface, the second reflective element is without gaps such that the second reflective element completely covers the second main surface. Electromagnetic radiation emerging at the second main surface in particular cannot penetrate through the second reflective element or can penetrate through it only to a small extent in directions perpendicular to the second main surface. The electromagnetic radiation is directed or guided by the second reflective element at least predominantly in directions transversely with respect to the surface normal to the second main surface, that is to say to the lateral radiation exit surface or surfaces of the semiconductor component.

It is also possible, in particular, for the second reflective element, with its side facing away from the semiconductor chip, to form a main surface of the radiation-emitting semiconductor component. That is to say that the second reflective element can, for example, adjoin a side surface of the radiation-emitting semiconductor component and with its outer surface form the top surface of the radiation-emitting semiconductor component. With its outer surface facing away from the semiconductor chip, the first reflective element can form the bottom surface of the radiation-emitting semiconductor component.

The second reflective element may be partly radiation-transmissive. That is to say that part of the electromagnetic radiation generated in the semiconductor chip may pass through the second reflective element, which results in radiation emerging at the top side of the semiconductor component facing away from the carrier. By way of example, at least 5% and at most 15% of the radiation emitted by the semiconductor component during operation emerges through the second reflective element. When the radiation-emitting semiconductor component is used in an optical waveguide, this can prove to be particularly advantageous since, with the semiconductor component switched on and the radiation exit surface of the optical waveguide at that outer surface of the second reflective element facing away from the semiconductor chip, the semiconductor component in the optical waveguide is no longer discernible or is only scarcely discernible as a dark location. In this way, no dark points or areas are produced by the semiconductor component in the emission surface of the optical waveguide.

The second and/or the first reflective element may be a reflective and electrically insulating layer, wherein the layer comprises a matrix material into which scattering or reflective particles are introduced. Such a layer then does not necessarily have a regular thickness. Rather, the layer can be structured in terms of its thickness. The layer can be produced, for example, by a dispensing method or a molding method or a coating method such as spray coating, for example. The matrix material of the reflective layer can be radiation-transmissive, for example, transparent. The reflective element then acquires the reflective effect by the particles introduced into the matrix material of the layer. The layer itself can then appear white or metallic.

The particles may consist at least of one of the materials TiO₂, BaSO₄, ZnO, AlₓO_{y}, ZrO₂ or contain one of the stated materials. Furthermore, the use of metal fluorides such as calcium fluoride or silicon oxide to form the particles is possible.

An average diameter of the particles, for example, a median diameter d₅₀ in Q₀, is preferably 0.3 μm to 5 μm. A proportion by weight of the particles in the material of the reflective layer is preferably 5% to 50% inclusive, in particular 10% to 30%. The particles can have a reflective and/or scattering effect.

The optical effect of the particles is based, for example, on their white color and/or on a difference in refractive index with respect to the matrix material of the layer.

The matrix material is, for example, a silicone, an epoxy or a silicone-epoxy hybrid material. However, it is also possible to use other radiation-transmissive plastics to form the matrix material.

The second and/or the first reflective element may be in direct contact with the assigned second or first main surface of the semiconductor chip at least in places. That is to say that in this example it is possible that, for example, both reflective elements touch the assigned main surface and are in direct contact therewith. In this way, it is possible to realize a radiation-emitting semiconductor component comprising only the semiconductor chip and the reflective elements applied to the semiconductor chip. This results in a very compact radiation-emitting semiconductor component.

The semiconductor chip may be fixed by its first main surface on a carrier. The carrier can be, for example, a circuit board, such as a printed circuit board, for instance. Furthermore, the carrier can be a metallic leadframe. Furthermore, it is possible for the carrier to be formed with an electrically insulating material such as a ceramic material, for example, onto which and/or into which electrical connection locations and conductor tracks are structured. That is to say that the carrier can serve, in particular, to electrically connect the semiconductor chip.

The carrier can furthermore form at least one part of the first reflective element. The semiconductor chip is fixed by its first main surface as a mounting surface on the carrier. The carrier can be, for example, reflective for the electromagnetic radiation generated in the semiconductor chip during operation such that the carrier then forms the first reflective element at the first main surface of the semiconductor chip. Additionally or alternatively, it is possible for an additional material such as, for example, an electrically insulating, reflective layer, as described above, to be arranged between the carrier and the first main surface, the layer then forming the reflective element. In this case, it is possible for the first reflective element to be formed exclusively by such a layer or for the carrier additionally to be reflective such that a reflection takes place at the layer and the carrier. Finally, it is also possible for the semiconductor chip to be reflectively coated at its first main surface facing the carrier. This can be effected by a metal layer, for example, which can be vapor-deposited onto the first main surface of the semiconductor chip.

The semiconductor chip may comprise at least one side surface running transversely with respect to the main surfaces of the semiconductor chip, wherein the semiconductor chip is surrounded by a radiation-transmissive encapsulation at least at the side surface. By way of example, the semiconductor chip can be surrounded with the encapsulation by a dispensing method or a molding method. In this case, it is possible for the encapsulation to cover all the side surfaces and the second main surface of the semiconductor chip. Furthermore, it is possible for the second main surface to be free of the radiation-transmissive encapsulation and only all the side surfaces of the semiconductor chip to be covered by the radiation-transmissive encapsulation. By way of example, the radiation-transmissive encapsulation is formed with a radiation-transmissive plastics material, as described further above for the matrix material. If the semiconductor component comprises the electrically insulating, reflective layer described above, then it is possible, in particular, for the matrix material and the radiation-transmissive encapsulation to be formed with the same material. In this case, the reflective layer, that is to say the first and/or the second reflective element, adheres particularly well to the radiation-transmissive encapsulation.

The radiation-transmissive encapsulation can be filled with radiation-scattering and/or radiation-absorbing particles. In this case, it is also possible, in particular, for the radiation-transmissive encapsulation to be filled with particles of a luminescence conversion material. By way of example, UV radiation and/or blue light can then be generated in the semiconductor chip during operation. The luminescence conversion material in the radiation-transmissive encapsulation then provides for complete or partial conversion such that the semiconductor component emits colored light, mixed radiation and/or white light during operation.

The radiation-transmissive encapsulation may delimit at least in places a cavity filled with the second reflective material. By way of example, the radiation-transmissive encapsulation encapsulates the semiconductor chip at all side surfaces and the second main surface. At the second main surface, a cutout can then be introduced into the radiation-transmissive encapsulation, the cutout being delimited by the material of the radiation-transmissive encapsulation and/or the second main surface of the semiconductor chip. In this way, the radiation-transmissive encapsulation delimits a cavity at least in places. The cavity can be filled with the second reflective element. That is to say that the second reflective element is arranged at least partly in the cavity. In this case, it is possible, in particular, for the outer surface of the radiation-transmissive encapsulation in direct contact with the second reflective element to be shaped in a predefinable manner. By way of example, the radiation-transmissive encapsulation can be concavely curved in this region. Beam shaping of the emerging radiation is then possible with the aid of the configuration of the outer surface of the radiation-transmissive encapsulation.

It is furthermore possible for the radiation-transmissive encapsulation to taper with regard to its thickness from the side surface of the radiation-emitting semiconductor component toward the semiconductor chip. In this case, the thickness is measured in a direction perpendicular to the two main surfaces of the semiconductor chip.

The semiconductor chip may comprise at its second main surface cutouts filled with the second reflective element. By way of example, the semiconductor chip can have at its second main surface a roughening that provides a multiplicity of cutouts in the main surface. These roughenings can be random or regular. The second main surface structured in this way can bring about a change in the coupling-out angle of the radiation emerging from the radiation-emitting semiconductor component. Furthermore, the probability of radiation emerging from the semiconductor chip is increased. The cutouts formed by the structuring can be filled with the material of the reflective element such that an efficient reflection of electromagnetic radiation generated in the semiconductor chip takes place.

The semiconductor component may comprise a reflective coating covering a connection location at one of the main surfaces of the semiconductor chip at least in places. The connection locations and/or, if appropriate, current distribution tracks at the outer surface of the semiconductor chip can be covered by the reflective coating, which possibly covers radiation-absorbing regions of the connection locations and/or of the current distribution tracks. The reflective coating can be formed with the same material as the second reflective element.

The radiation-emitting semiconductor component described here can be used for directly backlighting an imaging element, for example, an LCD panel. For this purpose, for example, a multiplicity of the radiation-emitting semiconductor components can be arranged on a common carrier, for example, a circuit board. That outer surface of the circuit board facing the semiconductor components can form or at least partly form the first reflective element.

A lighting device is furthermore specified. The lighting device can comprise, in particular, a radiation-emitting semiconductor component described here as a light source. That is to say that all features described for the semiconductor component are also disclosed for the lighting device.

The lighting device may comprise an optical waveguide and a radiation-emitting semiconductor component as described here. The optical waveguide comprises a cutout in which the radiation-emitting semiconductor component is arranged. The optical waveguide surrounds the semiconductor component at all its lateral radiation exit surfaces running transversely with respect to the main surfaces of the semiconductor chip. That is to say that the radiation of the semiconductor component emerging from the radiation exit surfaces is coupled into the optical waveguide in the region of the cutout in said optical waveguide. For this purpose, the optical waveguide can be formed with a radiation-transmissive, for example, transparent, material. By way of example, a reflector is arranged at a bottom surface of the optical waveguide. The radiation-emitting semiconductor component is preferably fixed in the cutout of the optical waveguide such that the first main surface of the semiconductor chip faces the reflector and the second main surface is directed away from the reflector. In this case, it is also possible for the reflector to be formed by the carrier of the radiation-emitting semiconductor component.

In the lighting device, the cutout in the optical waveguide may be a perforation. That is to say that the cutout extends through the entire optical waveguide. The optical waveguide has a hole in the region of the cutout. In this case, it is possible, for example, for the optical waveguide to be placed by the cutout onto the lighting device, and the lighting device in this way can be arranged in the cutout of the optical waveguide. The optical waveguide can then be fixed, for example, to the reflector, that is to say, for example, to the carrier of the lighting device.

The lighting device may comprise at least two of the radiation-emitting semiconductor components described here, wherein each radiation-emitting semiconductor component is arranged in a cutout of the optical waveguide. In particular, it is possible for the optical waveguide to comprise a multiplicity of cutouts, wherein a radiation-emitting semiconductor component described here is introduced into each cutout. In this way, a large-area optical waveguide can be illuminated particularly homogeneously. By virtue of the radiation-emitting semiconductor components that can be embodied particularly flat and by virtue of the coupling-in of the electromagnetic radiation of said semiconductor components over the entire area of the optical waveguide, a very flat optical waveguide and thus a very flat lighting device can be realized. In this case, the radiation-emitting semiconductor components can be drivable separately from one another, such that, for example, dimming of the semiconductor components can be carried out locally. In this way, the luminous intensity of the light emerging from the optical waveguide can be set locally. The lighting device thus combines the advantages of a so-called “edge light”, since it is very thin, with the advantages of direct lighting, on account of the efficient utilization of the electromagnetic radiation of the radiation-emitting semiconductor components.

A radiation exit surface of the optical waveguide may project above the outer surface of the second reflective element facing away from the semiconductor chip, or the outer surface terminates flush with the radiation exit surface of the optical waveguide. That is to say that the radiation exit surface of the optical waveguide runs transversely, for example, perpendicularly, with respect to the lateral radiation exit surfaces of the radiation-emitting semiconductor components. The optical waveguide has a thickness which substantially corresponds to the thickness of the semiconductor component.

We further provide a display device. The display device comprises at least one lighting device described here as backlighting device. All features disclosed for the semiconductor component described here and all features disclosed for the lighting device described here are therefore also disclosed for the display device. The display device furthermore comprises an imaging element, which can be, for example, a liquid crystal display. The lighting device backlights the imaging element, wherein the radiation exit surface of the optical waveguide faces the imaging element. With the lighting device described here, on account of its small thickness, a particularly thin display device can be realized, wherein local dimming can be carried out on account of the arrangement of the laterally emitting semiconductor components in recesses or cutouts of the optical waveguide and in a manner distributed over the entire area of the optical waveguide.

The semiconductor components described here, the lighting device and also the display device are explained in greater detail below on the basis of examples and the associated figures.

Elements that are identical, of identical type or act identically are provided with the same reference signs in the figures. The figures and the size relationships of the elements illustrated in the figures among one another should not be regarded as to scale. Rather, individual elements may be illustrated with an exaggerated size to enable better illustration and/or in order to provide a better understanding.

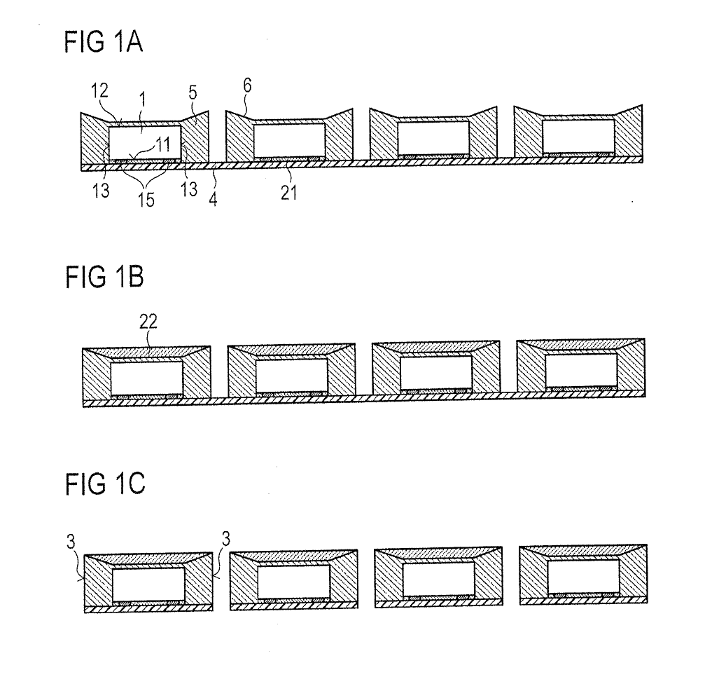

In conjunction with the schematic sectional illustration in FIG. 1A, a method step of producing a radiation-emitting semiconductor component 100 described here is explained in greater detail. In the first method step, a multiplicity of volume-emitting semiconductor chips 1 are arranged on a carrier 4. The volume-emitting semiconductor chip 1 is, for example, so-called “sapphire” chips comprising a radiation-transmissive sapphire growth substrate besides an epitaxially grown semiconductor body. The volume-emitting semiconductor chips 1 emit electromagnetic radiation through their first main surface 11, their second main surface 12 and the side surfaces 13.

The semiconductor chips 1 are arranged on a carrier 4. The carrier 4 is a printed circuit board, for example, which can be reflective. In this case, the semiconductor chips 1 are soldered or electrically conductively adhesively bonded to the carrier 4 by their connection locations 15. A first reflective element 21 is arranged between the first main surface 11 and the carrier 4. In this case, the first reflective element 21 is formed by a reflective electrically insulating layer. The electrically insulating element 21 therefore comprises an electrically insulating matrix material, for example, silicone, into which radiation-scattering and/or radiation-reflecting particles are introduced. Alternatively, it is possible for the first main surface 11 to be reflective in a different way, for example, by coating with a reflective material.

At all exposed outer surfaces of the semiconductor chips 1, the radiation-transmissive encapsulation 5 is applied by a molding method. That is to say that the radiation-transmissive encapsulation 5 adjoins the side surfaces 13 and the second main surface 12—situated opposite the first main surface 11—of the semiconductor chips 1. By way of example, the semiconductor chips 1 can be designed to generate blue light during operation. The radiation-transmissive encapsulation 5 then comprises particles of luminescence conversion substances which absorb part of the blue light and re-emit light having a higher wavelength, such that overall white mixed light can be emitted. Alternatively, it is possible for the semiconductor chips 1 to generate colored light which penetrates through the radiation-transmissive encapsulation 5 without being converted.

A cavity 6, as a result of the shaping of the mold tool, that is to say as a result of corresponding configuration of the radiation-transmissive encapsulation 5, can be configured such that the lateral coupling-out toward the radiation exit surfaces 3 is controlled. With the use of film methods, the second main surface 12 of the semiconductor chip can also remain free of the material of the radiation-transmissive encapsulation 5. A particularly thin semiconductor component can be realized in this way.

In a subsequent method step, FIG. 1B, a second molding method is carried out, wherein the second reflective element 22 is applied. In this case, the second reflective element 22 is introduced into the cavity 6 delimited by material of the radiation-transmissive encapsulation 5. Furthermore, interspaces between the individual semiconductor chips 1 in which the radiation-transmissive encapsulation 5 is not present can be filled with the material of the second reflective element 22. The second reflective material 22 can be, for example, an electrically insulating, reflective layer. The second reflective material 22 is then formed, for example, with a matrix material into which, as described above, reflective or scattering particles are introduced.

In a subsequent method step, the arrangement produced in this way is sawed apart or subjected to laser separation, cf. FIG. 1C. This results in individual radiation-emitting semiconductor components 100 described here. The radiation-emitting semiconductor components each have radiation exit surfaces 3 running transversely, in this case perpendicularly, with respect to the two main surfaces 11, 12 of the semiconductor chip 1. That is to say that the volume-emitting semiconductor chip 1, on account of the arrangement of the reflective elements 21, 22, becomes a side-emitting semiconductor component distinguished, in particular, by its small thickness, which is determined substantially by the thickness of the semiconductor chip 1. The radiation-transmissive encapsulation 5 has a decreasing thickness from the radiation exit surfaces 3 in the direction of the semiconductor chip 1. As a result of this configuration and the adjoining reflective elements, the electromagnetic radiation is guided out of the semiconductor component toward the side, that is to say toward the radiation exit surfaces 3.

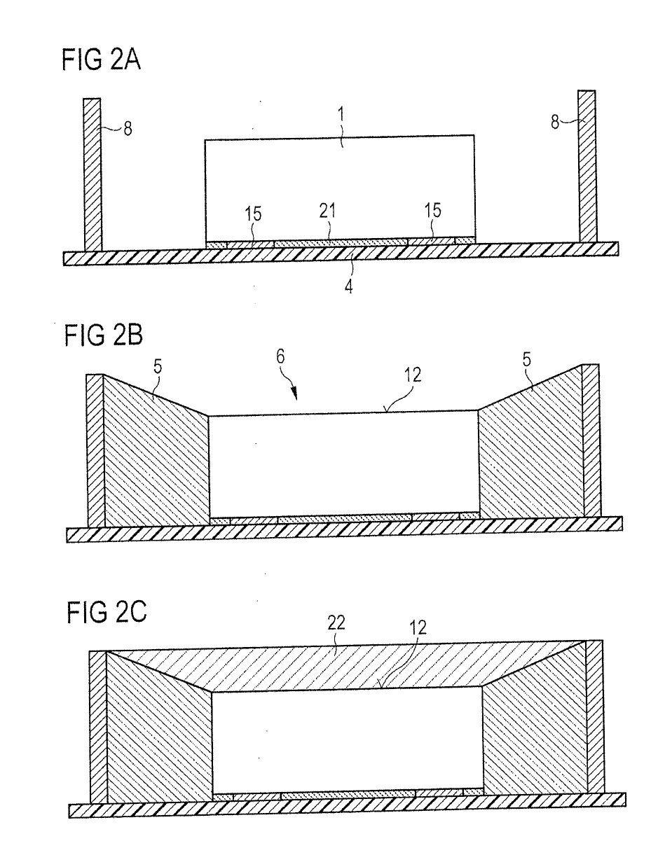

In conjunction with FIG. 2A, a first method step of a further method of producing a radiation-emitting semiconductor component described here is explained in greater detail. In this method, the volume-emitting semiconductor chips 1 are arranged on a carrier 4 in a similar manner to the method step in FIG. 1A. Barriers 8 are situated between the semiconductor chips 1 and demarcate the semiconductor components to be produced from one another. In addition, said barriers 8 serve to ensure that in the method step in FIG. 2B material of the radiation-transmissive encapsulation 5, the material being introduced by dispensing, for example, is drawn by adhesion forces to the upper edge of the barriers 8 facing away from the carrier 4. In this case, the material of the radiation-transmissive encapsulation 5 can be metered such that the radiation-transmissive encapsulation 5, at its side facing away from the barrier 8, terminates flush with the top side facing away from the carrier 4, that is to say the second main surface 12, of the semiconductor chip 1. As a result, a concavely curved meniscus of the radiation-transmissive encapsulation 5 can form between semiconductor chip 1 and barrier 8.

Subsequently, FIG. 2C, the second reflective element 22, for example, once again as a reflective layer, is filled into the cavity 6—delimited by the radiation-transmissive encapsulation 5 and the second main surface 12 of the semiconductor chip 1—as far as the upper edge of the barrier 8. A last method step involves separation into individual radiation-emitting semiconductor components, wherein the barrier 8 is removed by means of sawing, for example.

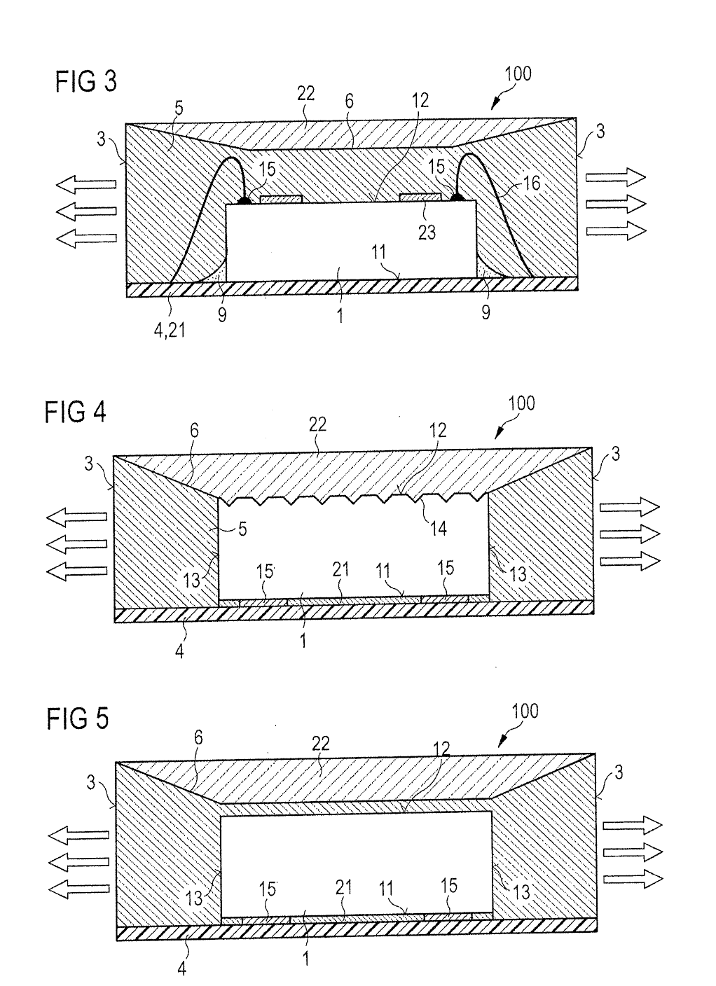

In conjunction with FIG. 3, a further example of a radiation-emitting semiconductor component described here is explained in greater detail with reference to a schematic sectional illustration. In this example, the connection locations 15 of the semiconductor chip 1 are arranged at that side of the semiconductor chip 1 facing away from the carrier 4. The connection locations 15 are formed with gold, for example, which is partly absorbent to visible light. The connection locations and/or, if appropriate, current distribution tracks at the outer surface of the semiconductor chip can be covered by a reflective coating 23, which possibly covers radiation-absorbing regions of the connection locations and/or of the current distribution tracks. The reflective coating 23 can be formed with the same material as the second reflective element 22.

The semiconductor chip 1 is adhesively bonded onto the carrier 4 by a connecting means 9, for example, an adhesive, the carrier 4 in this case also forming the first reflective element 21 at the first main surface 11 of the semiconductor chip 1. Alternatively or additionally, the semiconductor chip 1 can comprise as first reflective element a mirror coating of the first main surface 11, which can be a Bragg reflector, for example, and/or is provided by a metallic coating. The second reflective element 22 can be completely reflective, for example, such that radiation from the semiconductor chip 1 does not penetrate through it. In this case, the radiation-emitting semiconductor component constitutes an ideal side emitter. However, it is also possible for the second reflective element to be only partly reflective and for an, albeit small, proportion of the electromagnetic radiation generated in the chip to pass through the second reflective element. In this case, the top side of the radiation-emitting semiconductor component facing away from the carrier 4 is homogeneously illuminated.

In other words, the second reflective element can be partly radiation-transmissive. That is to say that part of the electromagnetic radiation generated in the semiconductor chip 1 passes through the second reflective element, which leads to an illumination of the top side of the semiconductor component facing away from the carrier. When the radiation-emitting semiconductor component is used in an optical waveguide, this can prove to be particularly advantageous since, with the semiconductor component switched on and the radiation exit surface of the optical waveguide at that outer surface of the second reflective element which faces away from the semiconductor chip, the semiconductor component in the optical waveguide is no longer discernible or is only scarcely discernible. In this way, no dark points or spots are produced by the semiconductor component in the emission surface of the optical waveguide.

The semiconductor chip 1 is electrically conductively connected to the carrier 4 by contact wires 16. The contact wires 16 are arranged completely within the radiation-transmissive encapsulation 5 and, on account of the second reflective element 22, are not discernible externally.

A large part of the electromagnetic radiation generated by the semiconductor chip 2 during operation is coupled out through the lateral radiation exit surfaces 3.

In conjunction with FIG. 4, a further example of a radiation-emitting semiconductor component described here is described with reference to a schematic sectional illustration. In this example, the semiconductor chip 1 comprises a second main surface 12, which comprises cutouts 14 filled with the second reflective element 22. The structured top side of the semiconductor chip 1, which top side can be a roughening, for example, leads to the change in the coupling-out angle of the electromagnetic radiation emitted by the semiconductor component during operation. A particularly flat construction of the radiation-emitting semiconductor component can be implemented in this way.

In the case of the example of the radiation-emitting semiconductor component shown in conjunction with the schematic sectional illustration in FIG. 5, the direct contact between the second reflective element 22 and the semiconductor chip 1 is dispensed with. However, the semiconductor component can advantageously be produced by a simple molding method (in this respect, also cf. FIGS. 1A to 1C).

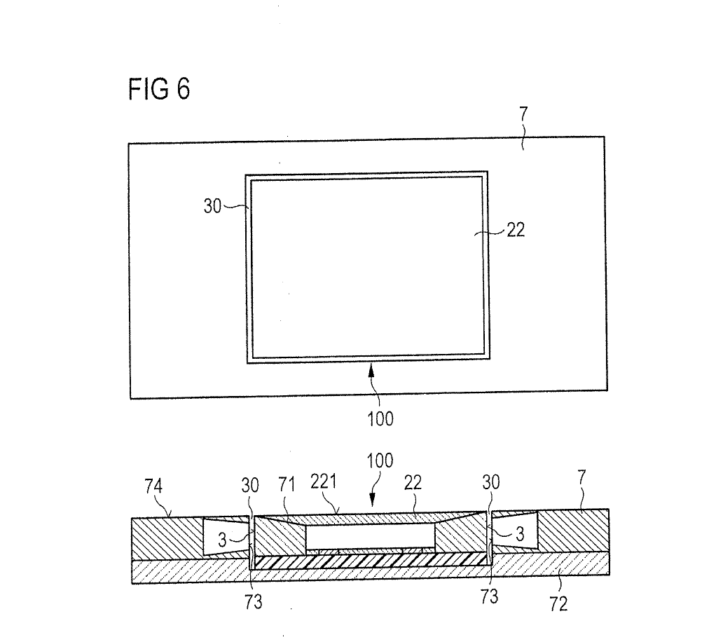

In conjunction with the schematic sectional illustrations in FIG. 6, one example of a lighting device described here is explained in greater detail.

The lighting device comprises an optical waveguide 7, into which a cutout 71 is introduced. The cutout 71 is filled with a radiation-emitting semiconductor component described here. A reflector 72 is arranged at the underside of the optical waveguide 7.

The top side of the optical waveguide 7 facing away from the reflector 72 forms the radiation exit surface 74 of the lighting device. For the case where the second reflective element 22 of the radiation-emitting semiconductor component 100 is also embodied as partly radiation-transmissive, a homogeneous luminous area can arise in view of the lighting device, as illustrated in FIG. 6.

After introduction of the semiconductor component, the trench 30 between the semiconductor component 100 and the radiation entrance surfaces 73 of the optical waveguide 7 can be filled with a radiation-transmissive material, for example, an index matching gel. This material can also serve for mechanically fixing the semiconductor component 100 in the optical waveguide 7.

As an alternative to the example illustrated in FIG. 6, it is also possible for the reflector 7 to be formed by the carrier of the semiconductor component 4. In this case, the optical waveguide can be slipped onto the semiconductor component 1 with cutouts 71 as perforations.

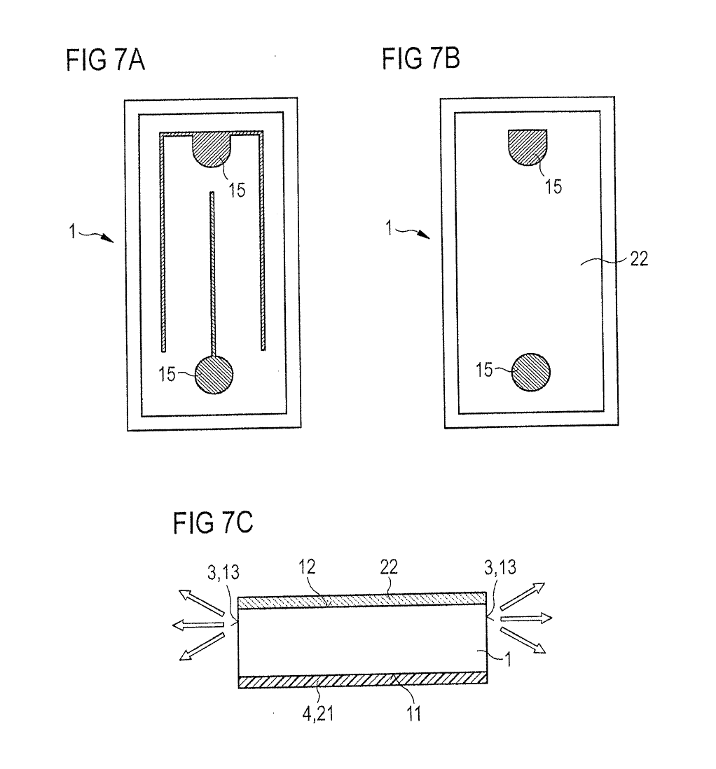

In conjunction with the schematic illustrations in FIGS. 7A, 7B and 7C, a further example of a radiation-emitting semiconductor component described here is explained in greater detail. In this example, the semiconductor chip 1 is coated with the material of the first reflective element 21 and of the second reflective element 22 at its first main surface 11 and its second main surface 12. By way of example, the first reflective material 21 can be formed by a rear-side mirror coating of the semiconductor chip 1 which is embodied in a metallic and/or dielectric fashion. By way of example, the layer can consist of aluminum or contain aluminum.

The second reflective element 22 can be, for example, a reflective layer as described above, containing a silicone as matrix material, for example, into which particles of titanium dioxide are introduced. In this case, the second reflective element 22 can be applied to the second main surface 12 of the semiconductor chip 1 as a layer of uniform thickness by spray coating, for example.

In this case, the second reflective element 22 can also cover current distribution tracks of the semiconductor chip 1. Connection locations 15 remain free of the reflective element 22 or are uncovered after the reflective element 22 has been applied.

This results in a radiation-emitting semiconductor component, wherein the side surfaces 13 of the semiconductor chip 1 form the lateral radiation exit surface 3 of the semiconductor component. Such a semiconductor component is distinguished by a very compact design, in particular.

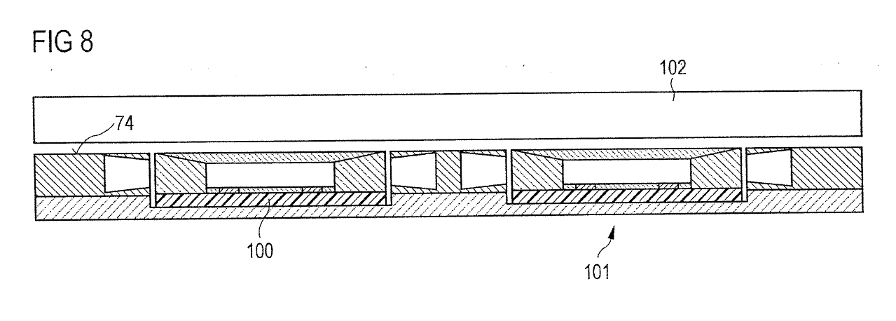

In conjunction with FIG. 8, a display device described here is explained in greater detail with reference to a schematic sectional illustration. The display device comprises a lighting device 101 described here, comprising a multiplicity of radiation-emitting semiconductor components described here, downstream of which the imaging element 102 is arranged at the radiation exit surface 74 of the lighting device 101, the imaging element being an LCD panel, for example.

Our components, devices and methods are not restricted to the examples by the description on the basis of those examples. Rather, this disclosure encompasses any novel feature and also any combination of features, which in particular includes any combination of features in the appended claims, even if the feature or combination itself is not explicitly specified in the patent claims or exemplary embodiments.

This patent application claims the priority of German patent application 102012102114.7, the disclosure content of which is hereby incorporated by reference.

1-16. (canceled)

17. A radiation-emitting semiconductor component comprising:
a volume-emitting semiconductor chip comprising a first main surface and a second main surface opposite the first main surface,
a first reflective element arranged at the first main surface and reflects electromagnetic radiation emerging through the first main surface during operation of the semiconductor chip back to the first main surface,
a second reflective element arranged at the second main surface and reflects electromagnetic radiation emerging through the second main surface during operation of the semiconductor chip back to the second main surface, and
at least one radiation exit surface through which electromagnetic radiation generated during the operation of the semiconductor component emerges from the semiconductor component,
wherein the at least one radiation exit surface runs transversely with respect to the first main surface and the second main surface of the semiconductor chip.

18. The radiation-emitting semiconductor component according to claim 17, wherein the semiconductor chip comprises at least one side surface running transversely with respect to the main surfaces, the semiconductor chip is surrounded by a radiation-transmissive encapsulation at least at the side surface, and the radiation-transmissive encapsulation delimits at least in places a cavity filled with the second reflective element.

19. The radiation-emitting semiconductor component according to claim 17, wherein the second reflective element completely covers the second main surface.

20. The radiation-emitting semiconductor component according to claim 17, wherein the second reflective element is partly radiation-transmissive and that side of the second reflective element facing away from the semiconductor chip forms a radiation exit surface of the radiation-emitting semiconductor component.

21. The radiation-emitting semiconductor component according to claim 17, wherein the second and/or the first reflective element are/is a reflective and electrically insulating layer, and the layer comprises a matrix material into which scattering or reflective particles are introduced.

22. The radiation-emitting semiconductor component according to claim 21, wherein the particles consist at least of one of the materials TiO₂, BaSO₄, ZnO, AlₓO_{y}, ZrO₂, metal fluoride, silicon oxide or contain one of the stated materials.

23. The radiation-emitting semiconductor component according to claim 17, wherein the second and/or the first reflective element are/is in direct contact with the assigned main surface of the semiconductor chip at least in places.

24. The radiation-emitting semiconductor component according to claim 17, wherein the semiconductor chip is fixed by its first main surface on a carrier, and the carrier forms at least one part of the first reflective element and/or the first reflective element is arranged at least partly between the carrier and the first main surface.

25. The radiation-emitting semiconductor component according to claim 17, wherein the semiconductor chip comprises at least one side surface running transversely with respect to the main surfaces, and the semiconductor chip is surrounded by a radiation-transmissive encapsulation at least at the side surface.

26. The radiation-emitting semiconductor component according to claim 25, wherein the radiation-transmissive encapsulation delimits at least in places a cavity filled with the second reflective element.

27. The radiation-emitting semiconductor component according to claim 17, wherein the semiconductor chip comprises at its second main surface cutouts filled with the second reflective element.

28. The radiation-emitting semiconductor component according to claim 17 comprising a reflective coating, which covers a connection location at one of the main surfaces of the semiconductor chip at least in places.

29. A lighting device comprising:
an optical waveguide, and
a radiation-emitting semiconductor component according to claim 17, wherein:
the optical waveguide comprises a cutout,
the radiation-emitting semiconductor component is arranged in the cutout, and
the optical waveguide surrounds the semiconductor component at at least one of the radiation exit surfaces.

30. The lighting device according to claim 29, wherein the cutout is a perforation.

31. The lighting device according to claim 29, comprising at least two radiation-emitting semiconductor components, wherein each radiation-emitting semiconductor component is arranged in a cutout of the optical waveguide.

32. The lighting device according to claim 29, wherein a radiation exit surface of the optical waveguide projects above the outer surface of the second reflective element that faces away from the semiconductor chip, or said outer surface terminates flush with the radiation exit surface of the optical waveguide.

33. A display device comprising:
a lighting device according to claim 29, and
an imaging element, wherein:
the lighting device backlights the imaging element, and
the radiation exit surface of the optical waveguide faces the imaging element.

34. A display device comprising:
a lighting device according to claim 30, and
an imaging element, wherein:
the lighting device backlights the imaging element, and
the radiation exit surface of the optical waveguide faces the imaging element.

35. A display device comprising:
a lighting device according to claim 31, and
an imaging element, wherein:
the lighting device backlights the imaging element, and
the radiation exit surface of the optical waveguide faces the imaging element.

36. A display device comprising:
a lighting device according to claim 32, and
an imaging element, wherein:
the lighting device backlights the imaging element, and
the radiation exit surface of the optical waveguide faces the imaging element.
